(19) United States
(12) Patent Application Publication
(10) Pub. No.: US 2025/0287525 A1
(43) Pub. Date: Sep. 11, 2025

(54) HEAT-DISSIPATING WATERPROOF CABINET

(71) Applicant: Fortune Electric Co., Ltd., Taoyuan City (TW)

(72) Inventors: CHIA-CHING LIN, Taoyuan City (TW); CHING-MIN CHEN, Taoyuan City (TW); CHIA-TAI HSU, Taoyuan City (TW)

(21) Appl. No.: 18/976,492

(22) Filed: Dec. 11, 2024

(30) Foreign Application Priority Data
Mar. 6, 2024 (TW) 113108041

(51) Int. Cl. H05K 7/20

(52) U.S. Cl. CPC H05K 7/20154; H05K 7/20145

(57) ABSTRACT

A heat-dissipating waterproof cabinet is provided and adapted to accommodate an electronic device. The heat-dissipating waterproof cabinet includes an inner cabinet body, at least one heat sink, and an outer cover. The inner cabinet body has an accommodation space and a plurality of ventilation holes and at least one heat dissipation window in spatial communication with the accommodation space. The at least one heat sink passes through the at least one heat dissipation window and is in thermal contact with a heat source of the electronic device. The outer cover houses the inner cabinet body and the at least one heat sink and shields the ventilation holes of the inner cabinet body. The outer cover has a plurality of heat dissipation holes that correspond in position to the at least one heat sink.

### CROSS-REFERENCE TO RELATED PATENT APPLICATION

This application claims the benefit of priority to Taiwan Patent Application No. 113108041, filed on Mar. 6, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an outdoor cabinet, and more particularly to a heat-dissipating waterproof cabinet, which is adapted to accommodate a voltage regulating device of a transformer being placed outdoors for a long period of time.

### BACKGROUND OF THE DISCLOSURE

With the promotion of grid construction, more and more electronic cabinets are used in power transmission and distribution systems, so as to protect electronic devices placed outdoors from environmental factors, such as communication devices, monitoring devices, and voltage regulating devices.

An electronic cabinet installed outdoors will inevitably be infiltrated by water, causing electronic devices in the cabinet to fail to operate normally. For example, in heavy rain, rainwater can enter the electronic cabinet from the top or sides of the cabinet. Therefore, the structural design of electronic cabinets requires waterproofing. In addition, not only are these electronic cabinets often directly exposed to strong sunlight, but the electronic devices within the cabinet will also generate heat, so that the temperature in the cabinet will increase. When the temperature in the cabinet is too high, the electronic devices will risk decreasing in service life or even be damaged.

However, striking a balance between waterproof functions and heat dissipation effects has always been a challenge in the related art. If a heat dissipation problem is solved, it would be difficult to achieve a good waterproof effect, and vice versa. Therefore, outdoor cabinets need to be improved in structure to increase resistance to rainwater and enhance heat dissipation and cooling performances, so as to overcome the above-referenced technical inadequacies.

### SUMMARY OF THE DISCLOSURE

In response to the above-referenced technical inadequacies, the present disclosure provides a heat-dissipating waterproof cabinet with good waterproof and heat dissipation capabilities, which can improve the reliability and service life of electronic components accommodated therein.

In order to solve the above-mentioned problems, one of the technical aspects adopted by the present disclosure is to provide a heat-dissipating waterproof cabinet, which is adapted to accommodate an electronic device. The heat-dissipating waterproof cabinet includes an inner cabinet body, at least one heat sink, and an outer cover. The inner cabinet body has an accommodation space and a plurality of ventilation holes and at least one heat dissipation window in spatial communication with the accommodation space. The at least one heat sink passes through the at least one heat dissipation window and is in thermal contact with a heat source of the electronic device. The outer cover houses the inner cabinet body and the at least one heat sink and shields the ventilation holes of the inner cabinet body. The outer cover has a plurality of heat dissipation holes that correspond in position to the at least one heat sink.

In conclusion, by virtue of the inner cabinet body having an accommodation space and a plurality of ventilation holes and at least one heat dissipation window in spatial communication with the accommodation space, the at least one heat sink passing through the at least one heat dissipation window and being in thermal contact with a heat source of the electronic device, the outer cover housing the inner cabinet body and the at least one heat sink and shielding the ventilation holes of the inner cabinet body, and the outer cover having a plurality of heat dissipation holes that correspond in position to the at least one heat sink, the heat-dissipating waterproof cabinet provided by the present disclosure can not only meet the heat dissipation requirements of high-power electronic components, but also achieve a high waterproof grade that is ideal for long-term outdoor use.

More specifically, the heat-dissipating waterproof cabinet provided by the present disclosure can fully utilize natural air for heat dissipation and prevent rainwater from entering the inner cabinet body through hollow structures (e.g., holes, openings, or gaps) in the heat-dissipating waterproof cabinet, thereby being highly practical in the field of outdoor cabinet. After testing, the heat-dissipating waterproof cabinet provided by the present disclosure can reach the waterproof grade of IPX6.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective exploded view of a heat-dissipating waterproof cabinet the present disclosure;

FIG. 2 is a schematic perspective assembled view of the heat-dissipating waterproof cabinet of the present disclosure;

FIG. 3 is another schematic perspective assembled view of the heat-dissipating waterproof cabinet of the present disclosure;

FIG. 4 is a schematic perspective view of an inner cabinet body of the heat-dissipating waterproof cabinet of the present disclosure;

FIG. 5 is another schematic perspective view of the inner cabinet body of the heat-dissipating waterproof cabinet of the present disclosure;

FIG. 6 is a schematic perspective view of an outer cover of the heat-dissipating waterproof cabinet of the present disclosure;

FIG. 7 is a schematic enlarged view of the inner cabinet body of the heat-dissipating waterproof cabinet of the present disclosure;

FIG. 8 is a schematic perspective exploded view of a heat-dissipating waterproof cabinet according to a second embodiment of the present disclosure;

FIG. 9 is a schematic view showing a use state of the heat-dissipating waterproof cabinet of the present disclosure; and

FIG. 10 is a schematic view showing another use state of the heat-dissipating waterproof cabinet of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

Striking a balance between waterproof functions and heat dissipation effects has always been a challenge in the related art. If a heat dissipation problem is solved, it would be difficult to achieve a good waterproof effect, and vice versa. Therefore, the present disclosure provides a heat-dissipating waterproof cabinet that adopts a double-layered design for inner and outer structures in combination with specific configurations of waterproof and heat dissipation mechanisms can achieve an effective balance between waterproof and heat dissipation capabilities.

### First Embodiment

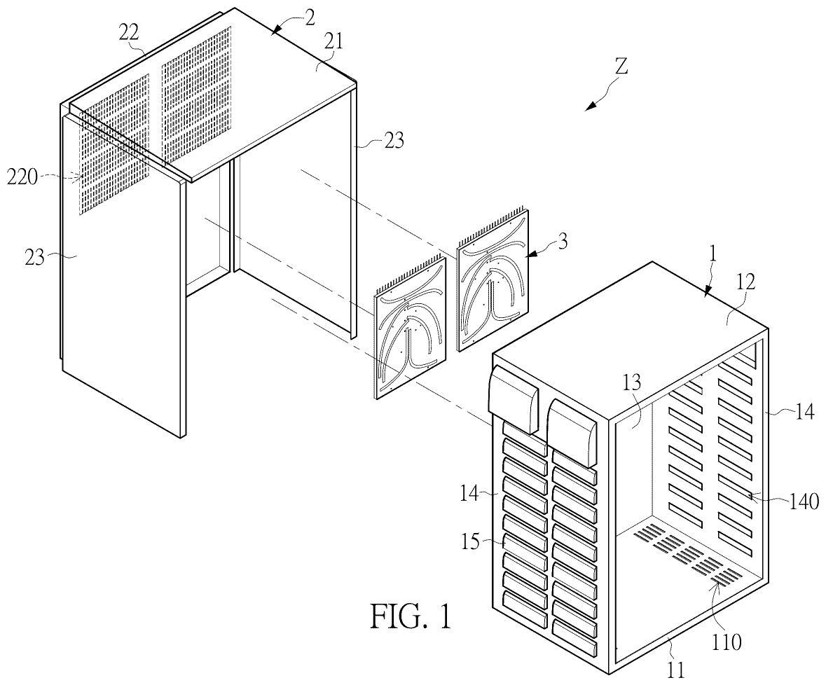

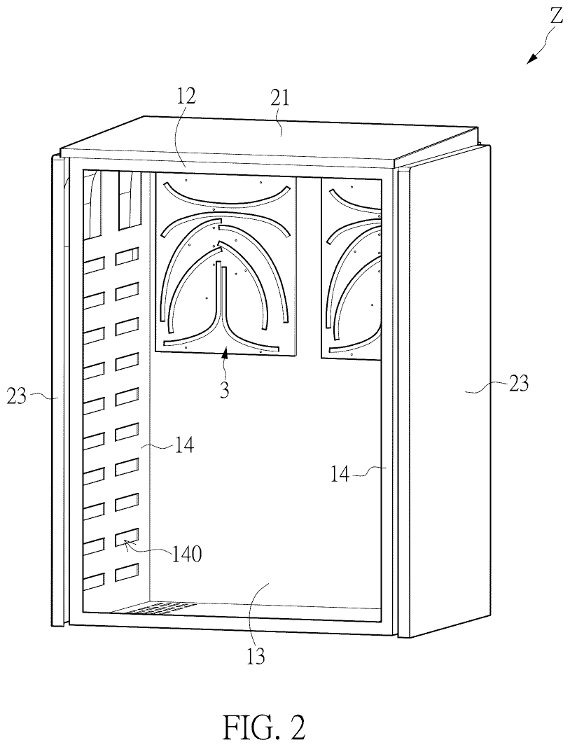

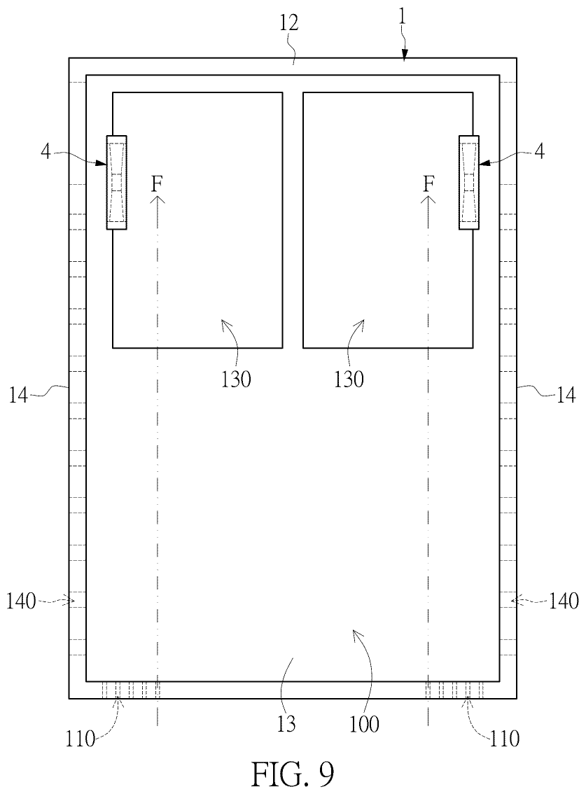

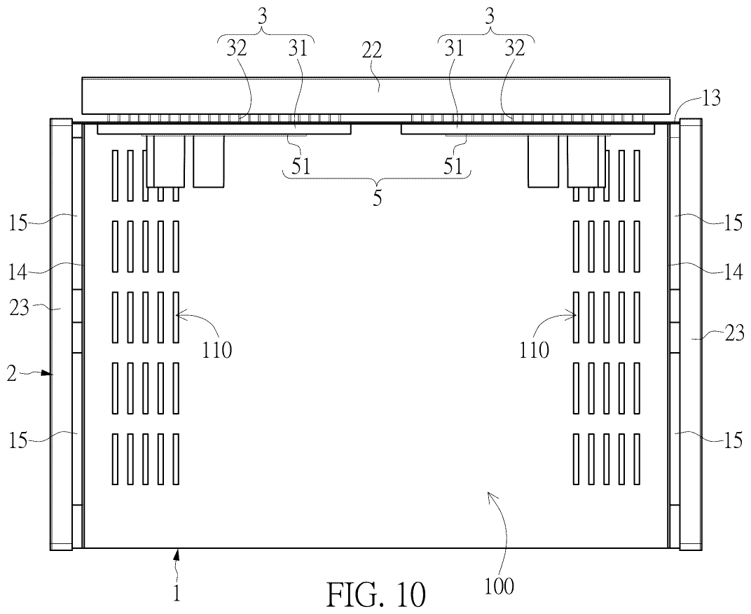

Referring to FIG. 1 and FIG. 2, which are to be read in conjunction with FIG. 9 and FIG. 10, the structure of a heat-dissipating waterproof cabinet Z according to an embodiment of the present disclosure is shown. The heat-dissipating waterproof cabinet Z of the present disclosure includes an inner cabinet body 1, an outer cover 2, and at least one heat sink 3. The at least one heat sink 3 is disposed on the inner cabinet body 1. The inner cabinet body 1 and the at least one heat sink 3 are housed in the outer cover 2. The heat-dissipating waterproof cabinet Z of the present disclosure is adapted to accommodate an electronic device 5 such as a device required for voltage regulation of a transformer in a power system. In use, the electronic device 5 can be disposed in an accommodation space 100 of the inner cabinet body 1 to have a double-layered protection against rain and solar radiation as provided by the inner cabinet body 1 and the outer cover 2. Furthermore, heat generated during the operation of the electronic device 5 can be continuously spread out and dissipated to the external environment by the at least one heat sink 3. The inner cabinet body 1 can cooperate with the outer cover 2 to allow sufficient ventilation and air exchange in the accommodation space 100, so as to fully utilize natural air for heat dissipation. More technical details will be provided in the following paragraphs.

In the present disclosure, the inner cabinet body 1 has a plurality of ventilation holes (i.e., first ventilation holes 110 and/or second ventilation holes 140 as shown in FIG. 2) and at least one heat dissipation window 130 in spatial communication with the accommodation space 100. The at least one heat sink 3 passes through the at least one heat dissipation window 130 and is in thermal contact with a heat source 51 of the electronic device 5, such as a voltage-regulating power board or a monitoring communication board. The outer cover 2 is configured to shield the ventilation holes of the inner cabinet body 1, and has a plurality of heat dissipation holes 220 that correspond in position to the at least one heat sink 3. The term “thermal contact” used herein refers to contact that can transfer heat effectively, such as direct contact or contact through a thermally conductive material (e.g., a thermally conductive adhesive) or a thermally conductive structure (e.g., a thermally conductive pad).

It is worth noting that the at least one heat sink 3 can not only increase the heat dissipation performance of the cabinet for more stringent requirements in heat dissipation, but also serve as a waterproof layer to prevent water from entering the inner cabinet body 1 through the at least one heat dissipation window 130.

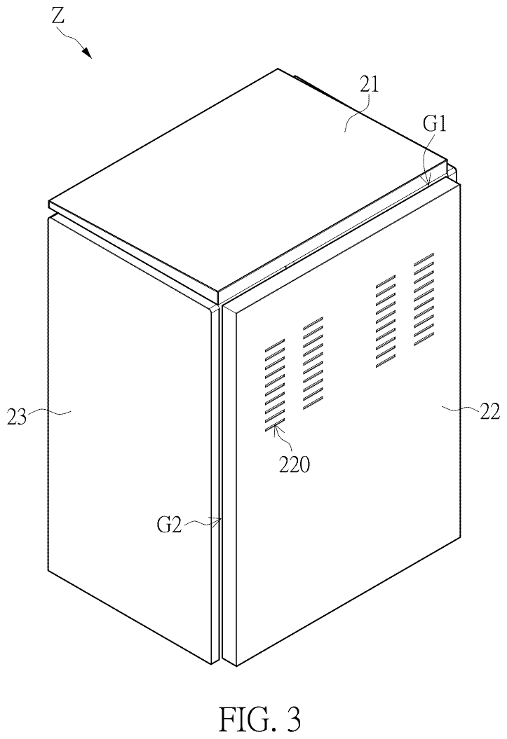

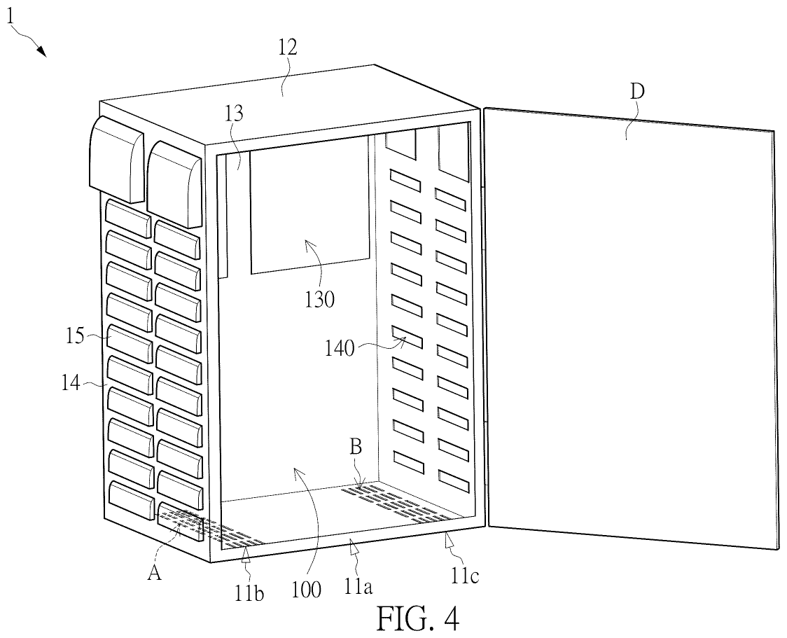

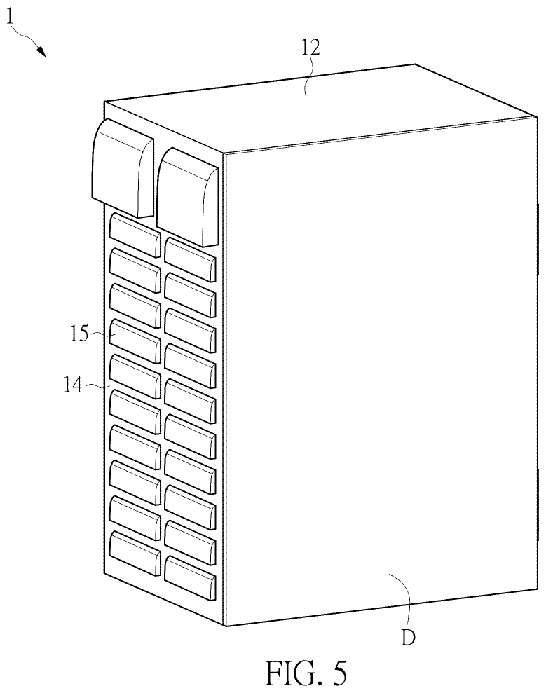

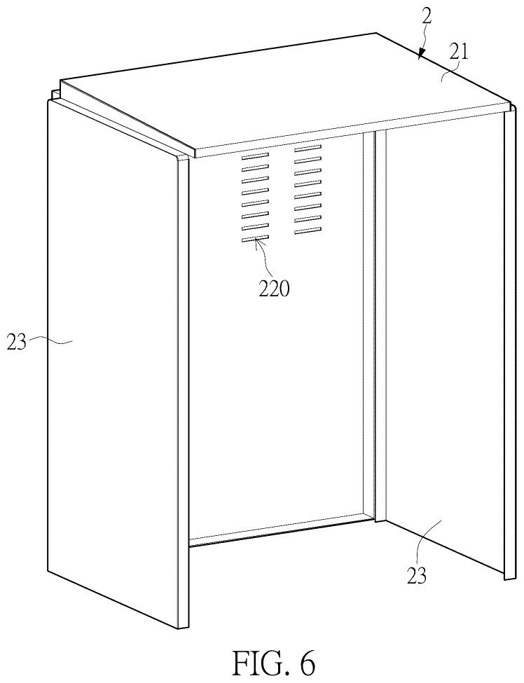

Reference is made to FIG. 3 to FIG. 6. The inner cabinet body 1 includes a bottom wall 11, a top wall 12, a rear wall 13, and two side walls 14 that jointly define the accommodation space 100. The bottom wall 11 is opposite to the top wall 12, and the rear wall 13 is integrally connected between the bottom wall 11 and the top wall 12. The two side walls 14 are, for example, left and right side walls, and are opposite to each other and integrally connected between the bottom wall 11, the top wall 12, and the rear wall 13. The inner cabinet body 1 can be made of stainless steel, but is not limited thereto. In addition, the outer cover 2 has a hollow section at the bottom thereof, which includes a top baffle 21, a rear baffle 22, and two side baffles 23. The top baffle 21 corresponds in position to the top wall 12 of the inner cabinet body 1. The rear baffle 22 corresponds in position to the rear wall 13 of the inner cabinet body 1. The two side baffles 23 respectively correspond in position to the two side walls 14 of the inner cabinet body 1. The outer cover 2 can be made of stainless steel, but is not limited thereto.

In practice, the heat-dissipating waterproof cabinet Z can include a cabinet door D that opens outwards. The cabinet door D is pivoted on the inner cabinet body 1, and can be flipped outwards relative to the inner cabinet body 1 to expose the accommodation space 100 or flipped inwards relative to the inner cabinet body 1 to close the accommodation space 100.

In a preferable embodiment, the bottom wall 11 of the inner cabinet body 1 is exposed from the hollow section of the outer cover 2, and a plurality of first ventilation holes 110 are arranged on the bottom wall 11. The top wall 12 of the inner cabinet body 1 is within the cover range of the upper baffle 21 of the outer cover 2, in which a ventilation space for airflow is present between the top wall 12 and the upper baffle 21. The rear wall 13 of the inner cabinet body 1 is within the cover range of the rear baffle 22 of the outer cover 2, in which a space for airflow is present between the rear wall 13 and the rear baffle 22 and in spatial communication with the external environment. Furthermore, the at least one heat dissipation window 130 is arranged on the rear wall 13, and the heat dissipation holes 220 are arranged on the rear baffle 22 and adjacent to the at least one heat dissipation window 130. Each of the two side walls 14 of the inner cabinet body 1 is within the cover range of the corresponding side baffle 23 of the outer cover 2, in which another space for airflow is present between each of the two side walls 14 and the corresponding side baffle 23 and in spatial communication with the external environment. Furthermore, the second ventilation holes 140 are arranged on the two side walls 14 and shielded by the two side baffles 23.

More specifically, the bottom wall 11 of the inner cabinet body 1 has a central area 11a and first and second peripheral areas 11b, 11c located at two opposite sides of the central area 11a. The first ventilation holes 110 are arranged on the bottom wall 11 into two ventilation hole arrays A, B. One of the two ventilation hole arrays A, B is located in the first peripheral area 11b and the other of the two ventilation hole arrays A, B is located in the second peripheral area 11c. Furthermore, one portion of the second ventilation holes 140 is arranged side-by-side in pairs on one of the two side walls 14, and the other portion of the second ventilation holes 140 is arranged side-by-side in pairs on the other of the two side walls 14. However, the aforementioned description for the arrangement of the first ventilation holes 110 and the second ventilation holes 140 is only an example, and is not meant to limit the scope of the present disclosure.

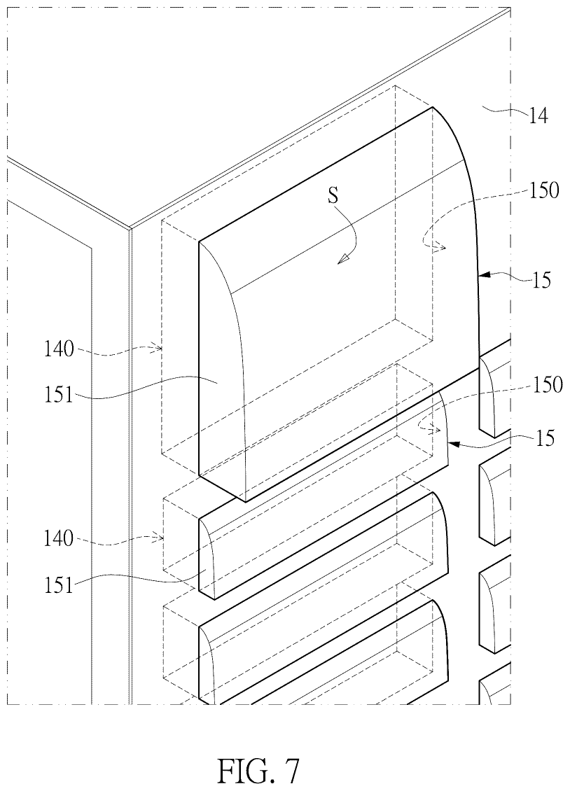

Reference is made to FIG. 2 and FIG. 3 along with FIG. 7 and FIG. 10. The rear baffle 22 and each of the two side baffles 23 of the outer cover 2 have a heat dissipation gap G1 therebetween. The rear baffle 22 and the top baffle 21 of the outer cover 2 have another heat dissipation gap G2 therebetween. Accordingly, at least one heat dissipation path can be shortened, thereby improving heat dissipation performance. In order to the improve waterproof performance of the cabinet, at least one shielding portion 15 can be disposed between the inner cabinet body 1 and the outer cover 2 to shield the second ventilation holes 140 of the two side walls 14 of the inner cabinet body 1. Therefore, the probability of water entering the inner cabinet body 1 and causing damage to the electronic device 5 can be greatly reduced. More specifically, each of the two side walls 14 and the corresponding side baffle 23 have a plurality of shielding portions 15 disposed therebetween that each shield one of the second ventilation holes 140, and each of the shielding portions 15 has an opening 150 that allows for air communication between the shielded second ventilation hole 140 and the external environment.

In practice, the shielding portions 15 can have the function of guiding and draining out rainwater, so as to avoid water accumulation between each of the two side walls 14 of the inner cabinet body 1 and the corresponding side baffle 23 of the outer cover 2. More specifically, each of the shielding portions 15 has a water shielding panel 151 that extends from an external wall surface of the corresponding side wall 14 to shield the corresponding second ventilation hole 140, and the water shielding panel 151 has a curved guiding surface S.

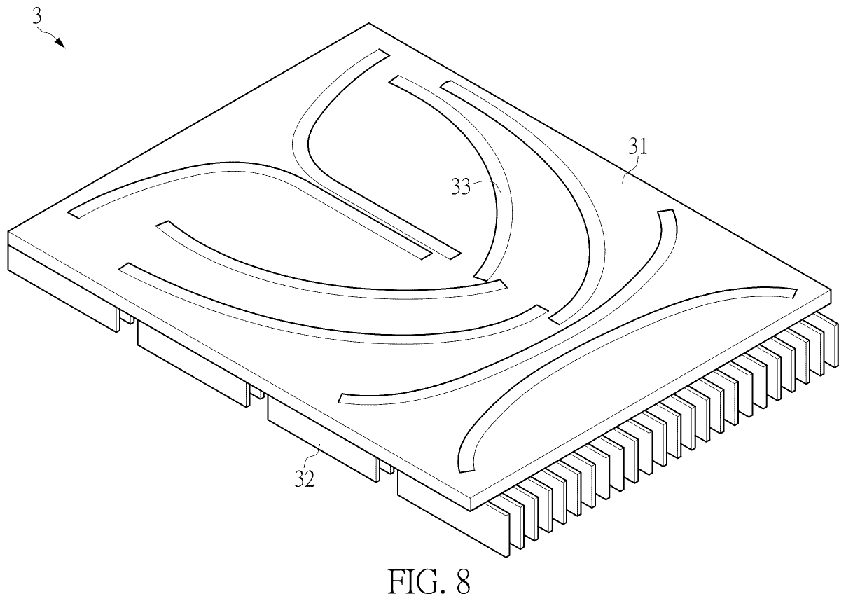

Reference is also made to FIG. 8. The heat sink 3 includes a base 31 and a plurality of heat dissipation fins 32 connected to the base 31. More specifically, the base 31 is located in the accommodation space 100 of the inner cabinet body 1 to be in contact or exchange heat with the heat source 51. The heat dissipation fins 32 are located between the rear wall 13 of the inner cabinet body 1 and the rear baffle 22 of the outer cover 2 and connected to the base 31 through the heat dissipation window 130. Preferably, the heat dissipation fins 32 are adjacent to the heat dissipation holes 220 of the rear baffle 22. According to particular requirements, the base 31 can have a plurality of heat pipes 33 buried therein to reduce temperature differences between different positions of the base 31. For example, the base 31 can be made of aluminum, the heat dissipation fins 32 can be made of an aluminum alloy, and the heat pipes 33 can be made of copper. However, the present disclosure is not limited by said specific examples.

Reference is also made to FIG. 9. The heat-dissipating waterproof cabinet Z of the present disclosure can further include at least one airflow driver 4 that is disposed in the accommodation space 100 of the inner cabinet body 1. The at least one airflow driver 4 is configured to produce at least one forced airflow from the first ventilation holes 110 to the at least one heat dissipation window 130, thereby fully utilizing natural air for heat dissipation. Therefore, heat accumulated in the inner cabinet body 1 can be promptly dissipated. The at least one airflow driver 4 can be at least one cooling fan that is installed at a position corresponding to the at least one heat dissipation window 130, but the present disclosure is not limited thereto.

In practice, the rear wall 13 of the inner cabinet body 1 can have two heat dissipation windows 130 in a side-by-side arrangement. One of the two heat dissipation windows 130 corresponds in position to the ventilation hole array A on the bottom wall 11 in an up-down direction, and the other of the two heat dissipation windows 130 corresponds in position to the ventilation hole array B on the bottom wall 11 in an up-down direction. Furthermore, two heat sinks 3 can be provided and respectively pass through the two heat dissipation windows 130. Two airflow drivers 4 can be provided and correspond in position to the two heat sinks 3 in a front-rear direction. However, the above description is disclosed for exemplary purposes only, and is not meant to limit the scope of the present disclosure.

### BENEFICIAL EFFECTS OF THE EMBODIMENTS

The heat-dissipating waterproof cabinet provided by the present disclosure can not only meet the heat dissipation requirements of high-power electronic components, but also achieve a high waterproof grade ideal for long-term outdoor use.

More specifically, the heat-dissipating waterproof cabinet provided by the present disclosure can fully utilize natural air for heat dissipation and prevent rainwater from entering the inner cabinet body through hollow structures (e.g., holes, openings, or gaps) in the heat-dissipating waterproof cabinet, thereby being highly practical in the field of outdoor cabinet. After testing, the heat-dissipating waterproof cabinet provided by the present disclosure can reach the waterproof grade of IPX6.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A heat-dissipating waterproof cabinet, adapted to accommodate an electronic device, comprising:
an inner cabinet body having an accommodation space and a plurality of ventilation holes and at least one heat dissipation window that are in spatial communication with the accommodation space;
at least one heat sink passing through the at least one heat dissipation window and being in thermal contact with a heat source of the electronic device; and
an outer cover housing the inner cabinet body and the at least one heat sink and shielding the ventilation holes of the inner cabinet body, wherein the outer cover has a plurality of heat dissipation holes that correspond in position to the at least one heat sink.

2. The heat-dissipating waterproof cabinet according to claim 1, wherein the at least one heat sink includes a base and a plurality of heat dissipation fins, the base is located in the accommodation space of the inner cabinet body, and the heat dissipation fins are located between the inner cabinet body and the outer cover and connected to the base through the at least one heat dissipation window.

3. The heat-dissipating waterproof cabinet according to claim 2, wherein the heat dissipation fins are adjacent to the heat dissipation holes.

4. The heat-dissipating waterproof cabinet according to claim 3, wherein the base has a plurality of heat pipes buried therein.

5. The heat-dissipating waterproof cabinet according to claim 1, further comprising at least one airflow driver that is disposed in the accommodation space of the inner cabinet body and configured to produce at least one forced airflow from the ventilation holes to the at least one heat dissipation window.

6. The heat-dissipating waterproof cabinet according to claim 1, wherein the inner cabinet body includes a bottom wall, a top wall, a rear wall, and two side walls that jointly define the accommodation space, the outer cover includes a top baffle, a rear baffle, and two side baffles, the top baffle corresponds in position to the top wall, the rear baffle corresponds in position to the rear wall, and the two side baffles respectively correspond in position to the two side walls; wherein the ventilation holes includes a plurality of first ventilation holes and a plurality of second ventilation holes, the first ventilation holes are arranged on the bottom wall, the at least one heat dissipation window is arranged on the rear wall, one portion of the second ventilation holes is arranged on one of the two side walls and shielded by the corresponding side baffle, and another portion of the second ventilation holes is arranged on the other of the two side walls and shielded by the corresponding side baffle.

7. The heat-dissipating waterproof cabinet according to claim 6, wherein each of the two side walls and the corresponding side baffle have a plurality of shielding portions disposed therebetween that each shield one of the second ventilation holes, and each of the shielding portions has an opening that provides for air communication between the shielded second ventilation hole and the external environment.

8. The heat-dissipating waterproof cabinet according to claim 7, wherein each of the shielding portions has a water shielding panel that extends from an external wall surface of the corresponding side wall and shields the corresponding second ventilation hole, and the water shielding panel has a curved guiding surface.

9. The heat-dissipating waterproof cabinet according to claim 6, wherein the rear baffle and each of the two side baffles have a heat dissipation gap therebetween, and the rear baffle and the top baffle have another heat dissipation gap therebetween.

10. The heat-dissipating waterproof cabinet according to claim 6, wherein the bottom wall has a central area and first and second peripheral areas located at two opposite sides of the central area, the first ventilation holes are arranged on the bottom wall into two ventilation hole arrays, and one of the two ventilation hole arrays is located in the first peripheral area, and another of the two ventilation hole arrays is located in the second peripheral area.

11. The heat-dissipating waterproof cabinet according to claim 6, wherein one portion of the second ventilation holes is arranged side-by-side in pairs on one of the two side walls, and another portion of the second ventilation holes is arranged side-by-side in pairs on another of the two side walls.
